(19) United States
(12) Patent Application Publication
(10) Pub. No.: US 2015/0097281 A1
(43) Pub. Date: Apr. 9, 2015

(54) SEMICONDUCTOR DEVICE

(71) Applicant: FUJI ELECTRIC CO., LTD., Kawasaki-shi (JP)

(72) Inventor: Shinichiro ADACHI, Matsumoto-city (JP)

(73) Assignee: FUJI ELECTRIC CO., LTD., Kawasaki-shi (JP)

(21) Appl. No.: 14/481,910

(22) Filed: Sep. 9, 2014

(30) Foreign Application Priority Data
Oct. 3, 2013 (JP) 2013-207877

(51) Int. Cl. H01L 23/42; H01L 23/373; H01L 23/46

(52) U.S. Cl. CPC H01L 23/42; H01L 23/46; H01L 23/3736
USPC 257/714

(57) ABSTRACT

A semiconductor device is disclosed. The semiconductor device is a power semiconductor module of a liquid-cooled type, which substantially prevents a cooling liquid from leaking out without providing additional working on a casing and without a providing high precision in a process for forming a sealing member and a groove for fitting the sealing member. The semiconductor device has a groove for fitting a sealing member that is formed not at the casing but at the base plate. The sealing member and the groove have widths that bring the sealing member made of an elastic material into contact with side surfaces of the groove intermittently.

### CROSS-REFERENCE TO RELATED APPLICATION

The entire disclosure of the inventor's corresponding Japanese patent application, Serial No. JP PA 2013-207877, filed Oct. 3, 2013, is hereby incorporated by reference.

### BACKGROUND OF THE INVENTION

1. Field of the Invention

The present invention relates to a semiconductor device and in particular to a power semiconductor module having a power semiconductor element mounted therein.

2. Description of the Related Art

In power semiconductor modules in recent years, liquid-cooled power semiconductor modules are employed to meet the requirement for improving power density. FIG. 6 shows a schematic sectional view of a conventional liquid-cooled power semiconductor module.

Referring to FIG. 6, a power semiconductor module 100 comprises a semiconductor element 101, an insulated circuit board 102, a metallic base plate 106 having protruding parts 110 such as fins, and a metallic casing 108 for circulating a cooling liquid 112, as disclosed in Patent Document 1.

In the power semiconductor module 100, a groove 109 is formed around the periphery of the opening of the casing 108 in contact with the base plate 106. A sealing member 107 made of an elastic material is fitted to the groove 109 and held by pressing the base plate 106 against the casing 108 with a fastening mechanism 111 such as bolts. Thus, the cooling liquid 112 is prevented from leaking out.

FIG. 7 is a schematic sectional view of another conventional power semiconductor module 200 of a liquid-cooled type as disclosed in Patent Documents 2 and 3. In this conventional example, the lower surface side of the base plate 106 is protruding downward, and a groove 114 is formed on the side surface of the protruding part. In the groove 114, a sealing member 107 is fitted. In this state, the opening of the casing 108 and the protruding part of the base plate 106 are fitted and the base plate 106 and the casing 108 are held with a fastening mechanism 111 such as bolts. Thus, the cooling liquid 112 is prevented from leaking out.

### [Patent Document 1]

Japanese Unexamined Patent Application Publication No. 2007-250918

### [Patent Document 2]

Japanese Unexamined Patent Application Publication No. 2006-019477

### [Patent Document 3]

Japanese Unexamined Patent Application Publication No. 2011-198998

In the conventional example disclosed in Patent Document 1, and shown in FIG. 6, a step is needed for forming the groove 109 on the periphery of the opening of the casing 108. A precision of ±50 μm is required in this step of forming the groove 109 in order to avoid leakage of cooling liquid 112, which needs a step of machining of a high working cost. Thus, a cost for manufacturing the semiconductor module increases.

In the conventional example disclosed in Patent documents 2 and 3 and shown in FIG. 7, a problem arises in a procedure of fitting the protruding part of the base plate 106 to the opening of the casing 108 that if the diameter of the sealing member 107 is too small with respect to the depth of the groove 114, the cooling liquid 112 may leak out, while the sealing member 107 is too large, the sealing member obstructs fitting the base plate 106 into the casing 108. Thus, a high accuracy is required for the dimensions of the sealing member 107 and the groove 114, which raises the manufacturing cost. In addition, a twisting force may be exerted on the sealing member 107 in the procedure of fitting into the casing 108. If this twisted configuration is held in the fitted state between the base plate 106 and the casing 108, the long term reliability of the sealing member 107 is deteriorated.

### SUMMARY OF THE INVENTION

The present invention has been made in view of the problems described above and an object of the present invention is to provide a semiconductor device, which is a power semiconductor module of a liquid-cooled type, that prevents the cooling liquid from leaking out without need for additional working on a casing and without requirement for a high precision in a process for forming a sealing member and a groove for fitting the sealing member.

In order to achieve the above object, a first aspect of the present invention is a semiconductor device that comprises: a semiconductor element; an insulated circuit board joined with the semiconductor element on a first principal plane of the insulated circuit board; a base plate, on a first principal plane of which joined is a second principal plane of the insulated circuit board, and having a protruding part provided at a second principal plane of the base plate and an annular groove around a periphery of the protruding part; and a sealing member made of an elastic material and fitted along the groove; wherein a periphery of an opening of a casing is disposed to be in contact with the sealing member; and the sealing member and side surfaces of the groove are intermittently in contact with each other.

The present invention provides a semiconductor device, which is a semiconductor module of a liquid-cooled type, that can be manufactured without need for additional working on a casing and without requirement for a high precision in a process for forming a sealing member and a groove for fitting the sealing member, thereby preventing the cooling liquid from leaking out at a low manufacturing cost.

### BRIEF DESCRIPTION OF DRAWINGS

FIGS. 1A and 1B are a sectional view and a bottom plan view, respectively, of a semiconductor device according to Embodiment Example 1 of the present invention;

FIGS. 2A, 2B, and 2C are an enlarged bottom plan view, a sectional view cut along the line A-A′ in FIG. 2A, and a sectional view cut along the line B-B′, respectively, of a base plate and a sealing member in the semiconductor device according to Embodiment Example 1 of the present invention;

FIGS. 3A and 3B are a sectional view of a semiconductor device and a bottom plan view of a base plate of the semiconductor device, respectively, according to Embodiment Example 2 of the present invention;

FIGS. 4A and 4B are a sectional view of a semiconductor device and a bottom plan view of a base plate of the semiconductor device, respectively, according to Embodiment Example 3 of the present invention;

FIGS. 5A, 5B, and 5C are an enlarged bottom plan view of a groove in a base plate and sealing member, a sectional view cut along the line C-C′ in FIG. 5A, and a sectional view cut along the line D-D′ in FIG. 5A, respectively, of the semiconductor device according to Embodiment Example 3 of the invention;

FIG. 6 is a sectional view of a conventional example of semiconductor device; and

FIG. 7 is a sectional view of another conventional example of semiconductor device.

### DETAILED DESCRIPTION OF THE INVENTION

Some preferred embodiments of the present invention will be described in detail in the following with reference to the accompanying drawings. Throughout the description of the embodiments, the same components are given the same symbol and repeated description is omitted.

The present invention is not limited to the embodiments described below but can be applied to any variations and modifications within the spirit and scope of the present invention.

### Embodiment Example 1

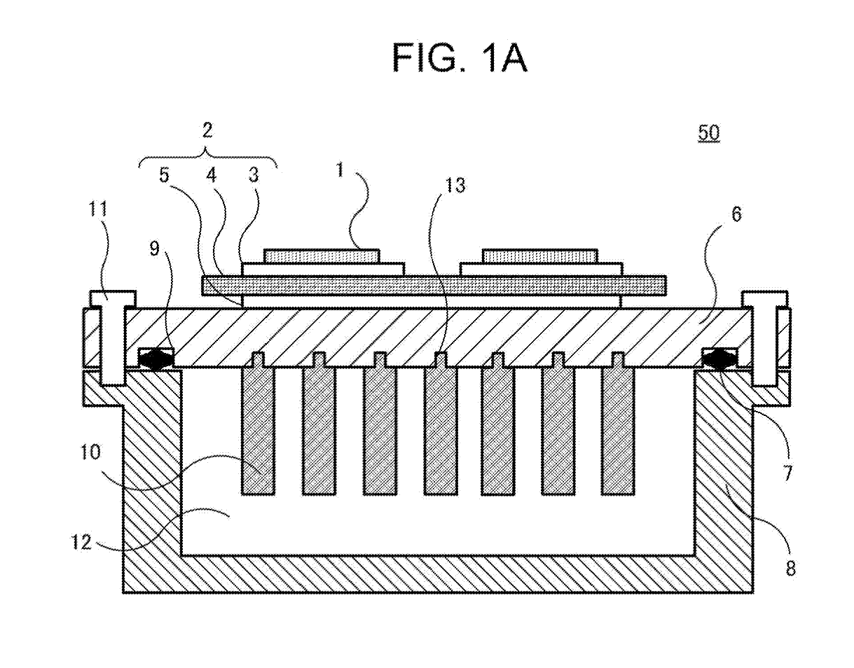

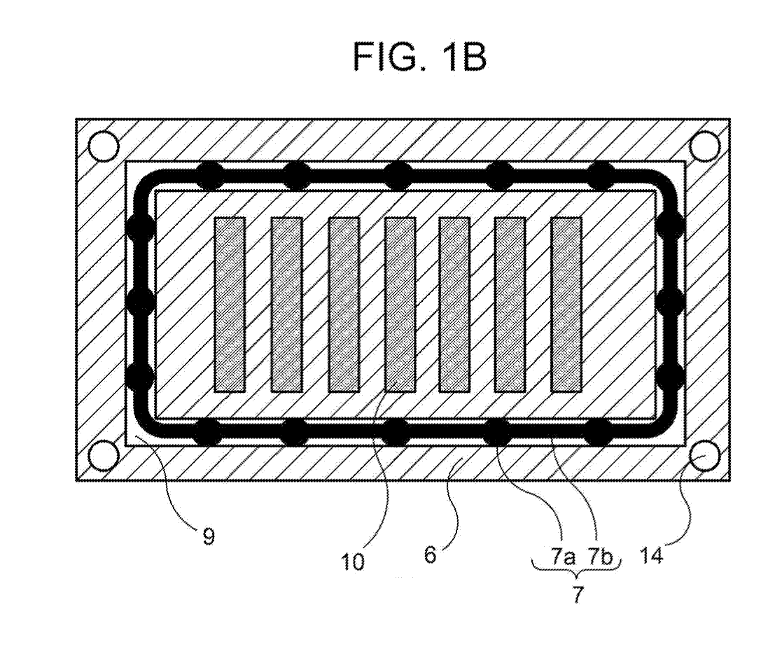

FIGS. 1A and 1B are a sectional view of an essential part and a bottom plan view, respectively, of a power semiconductor module 50 according to Embodiment Example 1 of the present invention.

The power semiconductor module 50 of FIGS. 1A and 1B comprises a semiconductor element 1, an insulated circuit board 2, a base plate 6 having a protruding part 10, and a casing 8 for containing cooling liquid 12.

The semiconductor 1 is a vertical type power semiconductor element such as an insulated gate bipolar transistor (IGBT), a power metal oxide semiconductor field effect transistor (power MOSFET), and a free-wheeling diode (FWD), for example. These semiconductor elements become at a high temperature in operation thereof, and thus, need to assure the heat dissipation thereof must be assured in order to achieve a high power density.

The insulated circuit board 2 is composed of three layers of a circuit pattern thin film 3, an insulating substrate 4, and a metal thin film 5. The insulating substrate 4 is made of ceramics such as sintered alumina Al₂O₃ or silicon nitride Si₃N₄, for example. The circuit pattern thin film 3 and the metallic thin film 5 are made of a metallic material with a main component of copper, and formed on the surfaces of the insulating substrate 4 by means of a direct copper bonding (DCB) method, for example. The circuit pattern thin film 3 has a circuit pattern necessary for the power semiconductor module 50, which is a semiconductor device.

On the surface of the circuit pattern thin film 3, a back surface electrode, for example a collector electrode, of at least one semiconductor element 1 is joined through a joining material such as a lead-free solder of Sn—Ag alloy (not shown in the figures).

The semiconductor element 1 is wired at the surface electrodes, for example an emitter electrode and a gate electrode, with bonding wires or metal plates to form an electric circuit necessary for the semiconductor module 50. The semiconductor element 1 is protected with an outer frame, a lid, and sealing resin provided around the semiconductor element 1, although those components are not depicted in the figure and description thereon is omitted here.

The base plate 6 has a shape of a plate and made of a metallic material of copper or a copper alloy. The material lets the heat generated in the semiconductor element 1 in operation of the semiconductor module 50 be effectively transferred to the cooling liquid 12, and improving heat dissipation performance. For this purpose, the base plate 6 is joined with the metallic thin film 5 of the insulated circuit board 2 through a joining material (not depicted in the figure) composed of lead free solder of a Sn—Ag alloy, for example.

The base plate 6 has a protruding part 10 such as fins provided on the surface opposite to the surface for joining the insulated circuit board 2. The protruding part 10 is provided for the purpose of increasing the contact area between the base plate 6 and the cooling liquid 12 to further improve heat dissipation performance. The protruding part 10 can be formed by forming recess 13 for fitting the parts composing the protruding part 10 at predetermined places on the principal surface of the base plate 6 with which the cooling liquid 12 is in contact. As shown in FIG. 1B, an annular groove 9 for fitting a sealing member 7 is formed surrounding the protruding part 10 on the periphery of the surface of the base plate 6 on which the protruding part 10 is formed.

The casing 8 has a configuration of a rectangular box having an opening and contains the cooling liquid 12 in the semiconductor module 50. The casing 8 is preferably composed of a metallic material of aluminum or an aluminum alloy. Those materials exhibit excellent durability in use of cooling liquid, and light weight of the material contributes to weight reduction of the semiconductor module 50.

The casing 8 is provided with an inlet and outlet for circulating the cooling liquid 12 through an external heat radiating device, although not illustrated and explained in the embodiment.

Between the base plate 6 and the casing 8, an annular sealing member 7 made of an elastic material is disposed fitting in the annular groove 9 for fitting the sealing member 7. The base plate 6 and the casing 8 are pressed against each other using a fastening mechanism 11 such as bolts and through-holes 14 formed in the base plate 6. Consequently, the elastic sealing member 7 fills throughout the gap between the base plate 6 and the casing 8, and thereby preventing the cooling liquid 12 from leaking out.

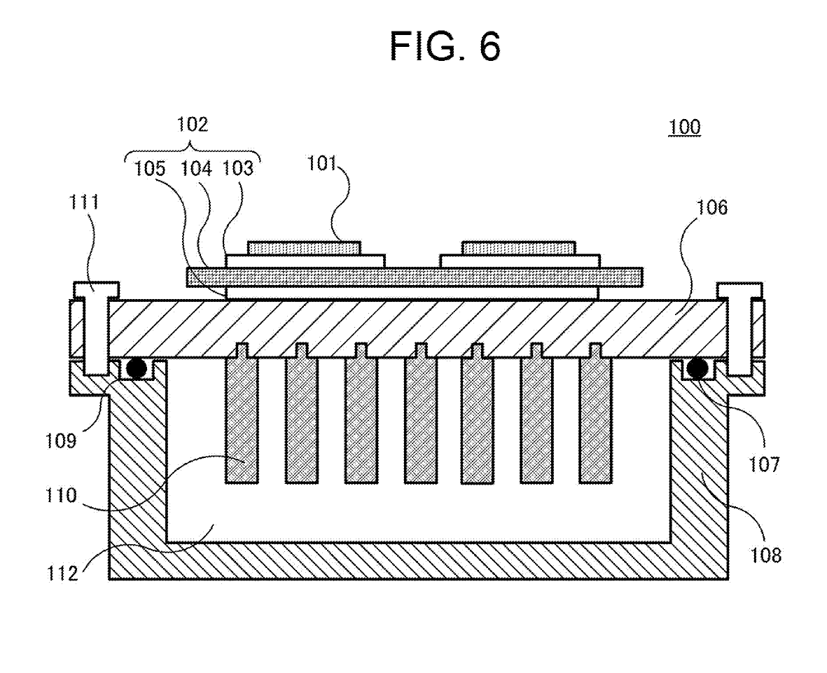

The semiconductor device according to the embodiment differs from the conventional example shown in FIG. 6 in that the groove 9 for fitting the sealing member 7 disposed between the base plate 6 and the casing 8 is formed not on the casing 8 but on the base plate 6 in the embodiment. Thus, the step for forming the groove for fitting the sealing member can be omitted in the embodiment, whereas the step is necessary in the case side in manufacturing a conventional device. As for the step of forming the groove 9 for fitting the sealing member 7 in the side of base plate 6 in the embodiment, the step can be carried out simultaneously with the step of forming the fitting recess 13 for fitting the protruding part 10, eliminating an additional step. Thus, the number of steps can be reduced in the manufacturing procedure as a whole and the manufacturing cost is decreased as compared with that in a procedure for manufacturing a conventional device. In the embodiment, the groove 9 and the fitting recess 13 can be formed using a molding die.

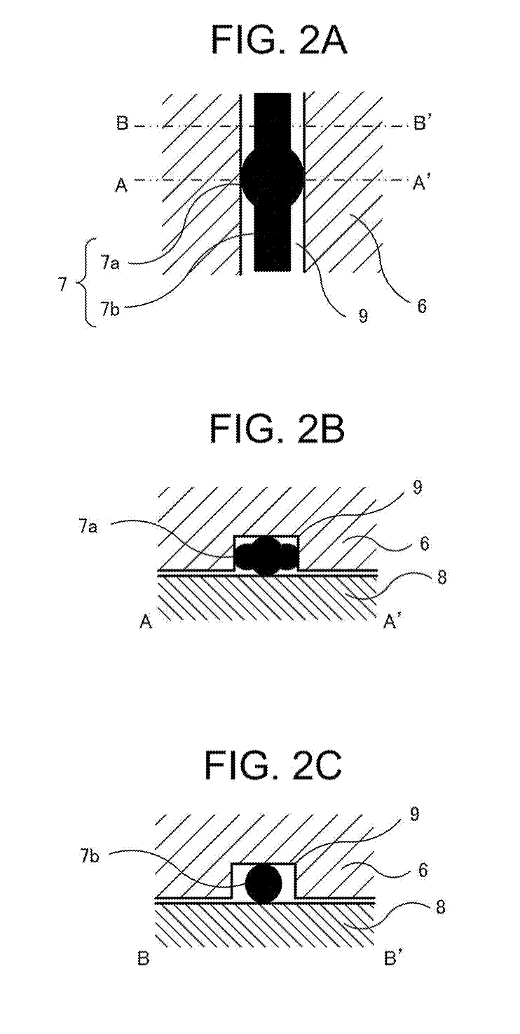

In the construction having a groove for fitting the sealing member in the side of the base plate, the sealing member would fall down from the fitted groove in the process of manufacturing a power semiconductor module. In order of avoid this happening, the sealing member in the embodiment has a construction having a wide sealing member part 7a and a narrow sealing member part 7b as shown in FIG. 1B. The elastically deformable sealing member 7 intermittently becomes in close contact with the side surfaces of the groove 9 holding the sealing member 7 in the groove 9. FIGS. 2A, 2B, and 2C show the construction around the sealing member 7 in detail.

FIG. 2A is an enlarged view of the wide sealing member part 7a, the narrow sealing member part 7b, and the groove 9 for fitting the sealing member 7 disposed on the base plate 6. FIG. 2B is a sectional view cut along the line A-A′ in FIG. 2A, and FIG. 2C is a sectional view cut along the line B-B′ in FIG. 2A.

As shown in FIG. 2B and FIG. 2C, the wide sealing member part 7a is wider than the narrow sealing member part 7b and wider than the groove 9 before fitting to the groove 9. Consequently, after squeezing wide sealing member part 7a into the groove 9 utilizing the elasticity of the material of the sealing member, the sealing member 7 is surely held in the groove 9. Upon being squeezed into the groove, the sealing member 7 composed of an elastic material closely fits to the inner wall of the groove 9 intermittently at the wide sealing member parts 7a. The height or a thickness dimension of the sealing member 7 is larger than the depth of the groove 9 so that the sealing member 7 becomes in close contact with the casing 8. Because the height of the wide sealing member part 7a is equal to the height of the narrow sealing member part 7b as shown in FIGS. 2B and 2C, the sealing member 7 fills the gap between the casing 8 and the base plate 6 uniformly throughout the groove 9.

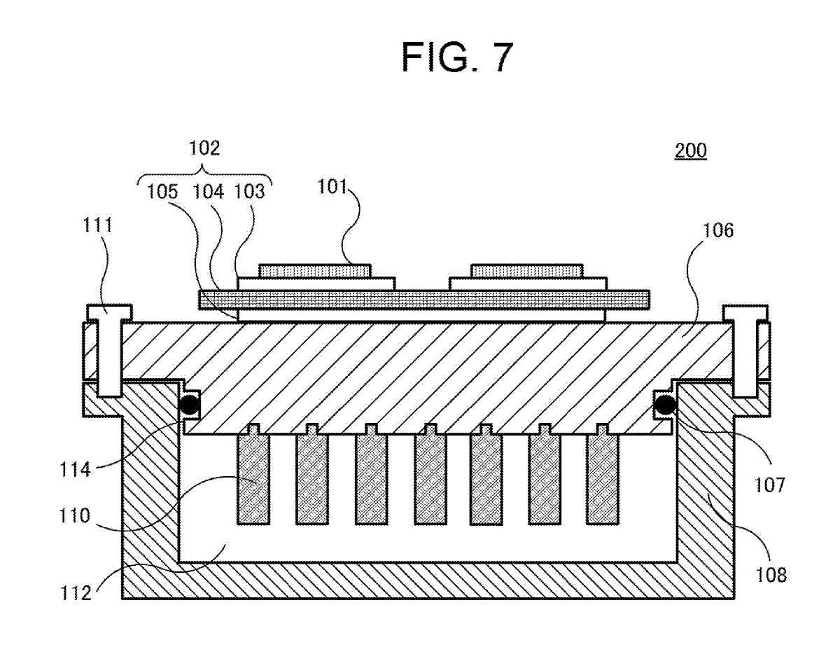

Comparing with the conventional example of FIG. 7, the embodiment holds the base plate 6 and the casing 8 by pressing them against each other. As a result, a dimensional error of the sealing member 7 and the groove 9 up to a certain degree can be absorbed by the elasticity of the sealing member 7. Therefore, the sealing member 7 and the groove 9 in the embodiment are allowed to be with a less dimensional precision. As a consequence, manufacturing costs are reduced. In addition, because no twisting force is exerted on the sealing member 7 in the process of assembling the base plate 6 and the casing 8, satisfactory long term reliability can be achieved as compared with the conventional example of FIG. 7.

It would be considered that the width of the annular sealing member is made larger than the width of the groove for fitting the sealing member continuously around whole the circumference and the sealing member is squeezed into the groove for fitting the sealing member. The sealing member in such a case can also be held in the groove in the base plate side like the case of the embodiment described above. However, it takes relatively long time to squeeze the sealing member into the groove throughout whole the circumference of the groove continuously. In the embodiment of the invention, because the width of the narrow sealing member part 7b is narrower than the width of the groove 9 as shown in FIG. 2C, the narrow sealing member part 7b can be put into the groove 9 without squeezing the sealing member 7. Consequently, the step of placing the sealing member 7 into the groove 9 is carried out readily in a relatively short time. Therefore, the manufacturing cost is restrained at a low level.

The sealing member 7 in the embodiment of the invention can be composed of a rubber material such as nitrile rubber, fluoro-rubber, and silicone rubber, using a molding die. Therefore, the sealing member having a configuration comprising wide sealing member parts 7a and narrow sealing member parts 7b can also be readily formed.

As shown in FIG. 1B, the groove 9 for fitting the sealing member 7 has an annular and rectangular shape. In this case, the wide sealing member parts 7a are provided at least one, preferably two or more, in each side of the rectangular shape for good holding of the sealing member 7 in the groove 9.

In the embodiment of the invention, the protruding part 10 can be formed using a material different from that of the base plate 6. For example, a material exhibiting better machinability can be employed and a protruding mart 10 with a rather complicated configuration but exhibiting better thermal dissipation can be formed and then disposed on the base plate 6.

The cooling liquid 12 in the embodiment can be water, for example. But the cooling liquid is not limited to water, but can be a liquid that exhibits a large specific heat to absorb enough heat, a liquid that exhibits a small viscosity to reduce a pressure drop in circulation of the cooling liquid, and a liquid that exhibits low reactivity with the materials composing the basic plate 6, the casing 8, the protruding part 10, and the sealing member 7 to ensure long term reliability.

### Embodiment Example 2

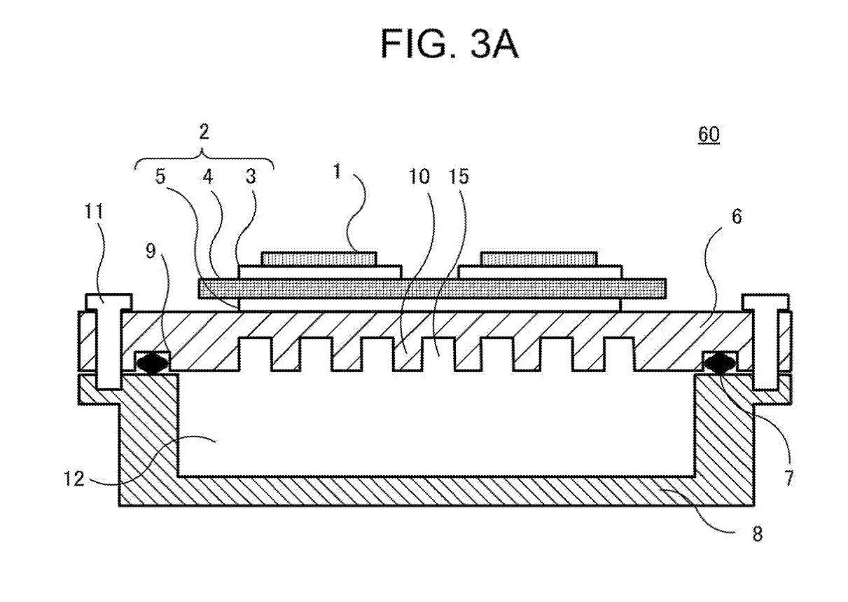

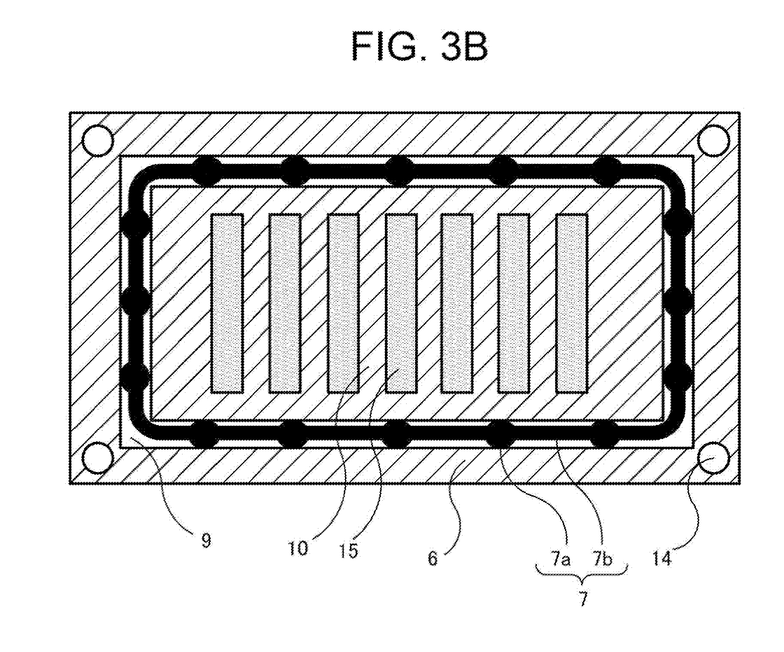

FIGS. 3A and 3B are a sectional view of an essential part and a bottom planar view of a power semiconductor module 60 according to Embodiment Example 2 of the invention.

The power semiconductor module 60 of the figures comprises, like the semiconductor module 50 of Embodiment Example 1, a semiconductor element 1, an insulated circuit board 2, a base plate 6 having a protruding part 10, and a casing 8 for containing cooling liquid 12.

The Embodiment Example 2 differs from Embodiment Example 1 in that a recess 15 is formed in the surface of the base plate in contact with the cooling liquid 12, which eventually forms a protruding part 10. This construction also increases the contact area between the base plate 6 and the cooling liquid 12, thereby improving heat dissipation performance.

In this Embodiment Example 2, too, the recess 15 can be formed simultaneously with the groove 9 for fitting the sealing member 7 by cutting. Thus, any additional step is not needed. Therefore, the manufacturing costs can be reduced as in Embodiment Example 1.

### Embodiment Example 3

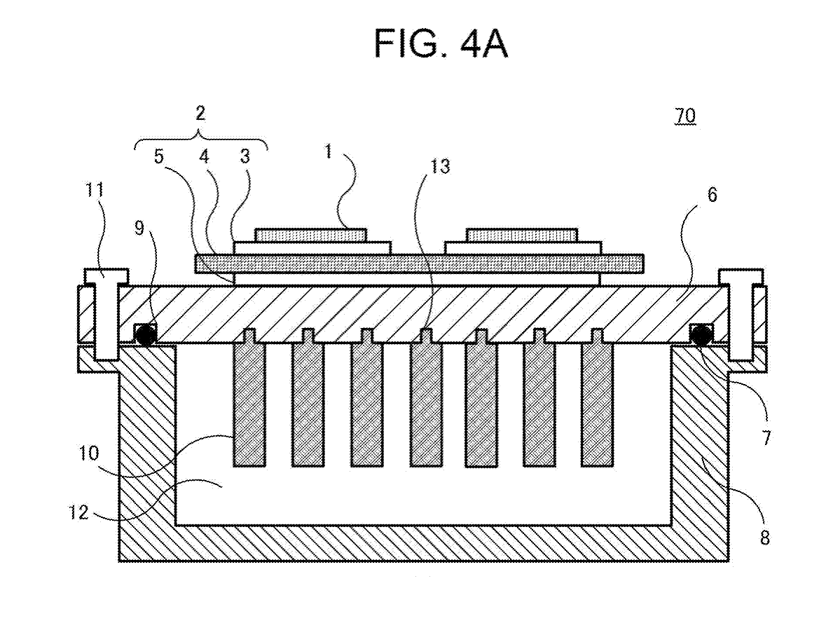

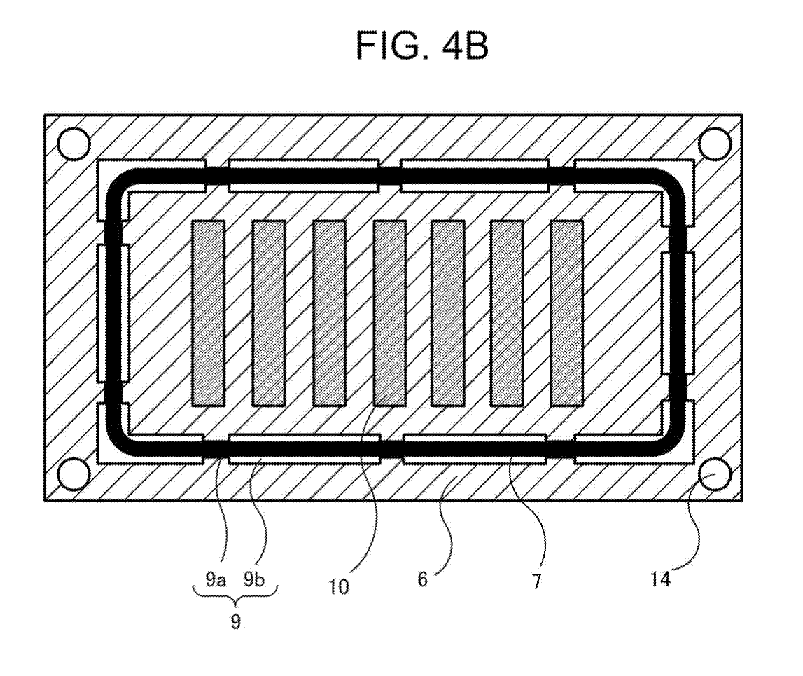

FIGS. 4A and 4B are a sectional view of an essential part and a bottom planar view of a power semiconductor module 70 according to Embodiment Example 3 of the invention.

The power semiconductor module 70 of the figures comprises, like the semiconductor module 50 of Embodiment Example 1, a semiconductor element 1, an insulated circuit board 2, a base plate 6 having a protruding part 10, and a casing 8 for containing the cooling liquid 12.

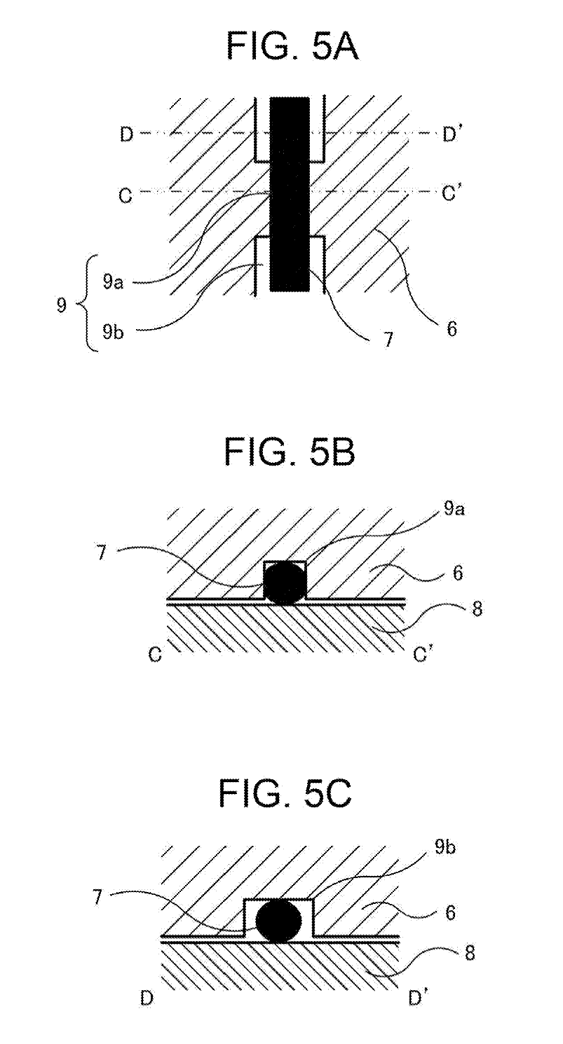

The Embodiment Example 3 is similar to the Embodiment Example 1 in that the sealing member 7 is made in close contact intermittently with the side walls of the groove 9 and held in the groove 9. And the Embodiment Example 3 differs from Embodiment Example 1 in that whereas the sealing member 7 has a uniform width throughout the whole circumference, the groove 9 is composed of narrow groove parts 9a and wide groove parts 9b. FIGS. 5A, 5B, and 5C shows this construction in detail.

FIG. 5A is an enlarged view of the sealing member 7 and the narrow groove part 9a and a wide groove part 9b of the groove 9 formed on the base plate 6 for fitting the sealing member 7. FIG. 5B is a sectional view cut along the line C-C′ of FIG. 5A, and FIG. 5C is a sectional view cut along the line D-D′ in FIG. 5A.

As shown in FIGS. 5B and 5C, the narrow groove part 9a has a width narrower than that of the wide groove part 9b and also narrower than that of the sealing member 7 before disposing in the groove. Thus, the sealing member 7 can be held in the groove 9 by squeezing the sealing member 7 into the narrow groove part 9a utilizing the elasticity of the sealing member 7. The sealing member 7 made of an elastic material, upon being squeezed into the groove 9, the side walls of the narrow groove part 9a becomes in close contact with the sealing member 7. This configuration allows the sealing member 7 to be held in the groove 9. Because the depths of the narrow groove part 9a and the wide groove part 9b are equal as shown in FIGS. 5B and 5C, the sealing member 7 fills the gap between the casing 8 and the base plate 6 uniformly around whole the circumference of the groove.

In this Embodiment Example 3, too, the step of forming the groove 9 for fitting the sealing member 7 in the base plate 6 can be conducted simultaneously with the step of forming the fitting recess 13 for fitting the protruding part 10 by means of molding. When the groove 9 composed of the narrow groove parts 9a and the wide groove parts 9b of FIGS. 5A, 5B, and 5C is employed in combination with the recess 15 and the protruding part 10 shown in FIGS. 3A and 3B, the step of forming the groove 9 in Embodiment Example 3 can be conducted simultaneously with the step of forming the recess 15 for forming the protruding part 10 by means of cutting. Therefore, no additional step is needed and the manufacturing cost is reduced as compared with that in manufacturing a conventional device.

In this Embodiment Example 3 as shown in FIG. 5C, the wide groove part 9b is wider than the sealing member 7. Consequently, the sealing member 7 can be placed in the groove without squeezing. This allows the step of disposing the sealing member in the groove to be carried out readily in a short time, which limits the manufacturing cost at a low value.

As shown in FIG. 4B, the groove 9 for fitting the sealing member 7 has an annular and rectangular shape. In this case, the narrow groove parts 9a are provided at least one, preferably two or more, in each side of the rectangular shape for good holding of the sealing member 7 in the groove 9.

It will be apparent to those skilled in the art that various modifications and variations can be made to the disclosed method and apparatus. Other embodiments will be apparent to those skilled in the art from consideration of the specification and practice of the disclosed method and apparatus. It is intended that the specification and examples be considered as exemplary only, with a true scope being indicated by the following claims and their equivalents.

What is claimed is:

1. A semiconductor device, comprising:
a semiconductor element;
an insulated circuit board joined with the semiconductor element on a first principal plane of the insulated circuit board;
a base plate, the base plate having a first principal plane to which is joined a second principal plane of the insulated circuit board, and having a protruding part provided at a second principal plane of the base plate and an annular groove disposed around a periphery of the protruding part; and
a sealing member made from an elastic material and fitted along the groove;
wherein a periphery of an opening of a casing is in contact with the sealing member; and
wherein the sealing member and side surfaces of the groove are intermittently in contact with each other.

2. The semiconductor device according to claim 1, wherein the sealing member includes a wide sealing member part and a narrow sealing member part, the wide sealing member part being wider than the groove before fitting the sealing member into the groove, and the narrow sealing member part being narrower than the groove.

3. The semiconductor device according to claim 1, wherein the groove includes a narrow groove part and a wide groove part, the narrow groove part being narrower than the sealing member before fitting the sealing member into the groove, and the wide groove part being wider than the sealing member.

4. The semiconductor device according to claim 1, wherein a cooling liquid circulates in contact with the second principal plane of the base plate.

5. The semiconductor device according to claim 1, wherein the protruding part attached to the base plate includes a member that is different from a member composing the base plate.

6. The semiconductor device according to claim 1, wherein the semiconductor element is a vertical type power semiconductor element.

7. The semiconductor device according to claim 1, wherein the base plate is made of copper or a copper alloy.
